(19) United States
(12) Patent Application Publication
(10) Pub. No.: US 2007/0284654 A1
(43) Pub. Date: Dec. 13, 2007

(54) METAL ALLOY LAYER OVER CONDUCTIVE REGION OF TRANSISTOR DEVICE OF DIFFERENT CONDUCTIVE MATERIAL THAN CONDUCTIVE REGION

(76) Inventors: Judith M. Rubino, Ossining, NY (US); James Pan, Fishkill, NY (US); Dinkar Singh, White Plains, NY (US); Jonathan Smith, Bristow, VA (US); Anna Topol, Wappingers Falls, NY (US)

Correspondence Address: HOFFMAN, WARNICK & D'ALESSANDRO LLC, 75 STATE ST, 14TH FL, ALBANY, NY, 12207, US

(21) Appl. No.: 11/422,965

(22) Filed: Jun. 8, 2006

(51) Int. Cl. H01L 29/76

(52) U.S. Cl. 257/327

(57) ABSTRACT

A transistor device and method are disclosed for reducing parasitic resistance and enhancing channel mobility using a metal alloy layer over a conductive region. A transistor device may include a conductive region such as a source, drain and/or gate including at least one first conductive material, and a metal alloy layer disposed on substantially all of a surface of the conductive region, the metal alloy layer including a second conductive material different than the at least one first conductive materials. In one embodiment, the second conductive material includes a cobalt and/or nickel alloy. The metal alloy layer provides a non-epitaxial raised source/drain (and gate) to reduce the parasitic series resistance in, for example, nFETs fabricated on UTSOI. In addition, the metal alloy layer may include a stress to enhance mobility in a channel of the transistor device. The metal alloy layer may be formed using a selective electrochemical metal deposition process such as electroless or electrolytic plating.

### BACKGROUND OF THE INVENTION

1. Technical Field

The invention relates generally to semiconductor device fabrication, and more particularly, to a method and transistor device including a metal alloy layer over substantially all of a conductive region, the metal alloy layer being made of a different conductive material than the conductive region.

2. Background Art

Ultra-thin silicon on insulator complementary metal oxide semiconductor (CMOS) transistors are advantageous because they provide improved short channel control, reduced parasitic junction capacitance and minimal floating body and history effects. One challenge in fabricating high performance UTSOI devices is the external parasitic source drain resistance (Rs/d). Resistance depends on the barrier height at the silicide-silicon interface and sheet resistance of the silicon underneath the silicide. As total silicon thickness is scaled in the source-drain regions, resistance increases. Typically, as shown in FIG. 1, an epitaxial raised-source drain (RSD) 10 is implemented to address this issue. For a given silicide 12 thickness, this approach decreases the sheet resistance of an underlying silicon 14, and therefore decreases contact resistance. (Buried silicon oxide (BOX) 16 and silicon substrate 18 are shown under silicon 14). However, the RSD process adds significant device integration complexity. For example, the pre-epitaxial surface cleans and epitaxial growth conditions are sensitive to the underlying dopant species and their concentration and require extensive optimization. In addition, the RSD process requires a fully encapsulated gate 8, as shown in FIG. 1, which adds a significant number of process steps and constrains integration and design options. For example, spacers (not shown) must be removed, which causes silicon 14 loss, especially when silicon 14 is below 10 nm in thickness. Another approach to this problem is to make silicide 16 very thin. However, this approach increases silicide resistance, yielding high parasitic resistance.

Another challenge is presented by use of thinner silicon 14 in current SOI technology. In particular, it is known in the art that tensile stress in a channel 20 enhances electron mobility in an nFET type transistor device, and a compressive stress enhances hole mobility in a pFET type transistor device. The coupling of stress to channel 20 of a transistor device however is becoming more difficult because the thinner silicon 14 necessitate thinner silicide 12 to provide lower contact resistance, which reduces the effect of stress on channel 20 normally imparted by the silicide.

### SUMMARY OF THE INVENTION

A transistor device and method are disclosed for reducing parasitic resistance and enhancing channel mobility using a metal alloy layer over a conductive region. A transistor device may include a conductive region such as a source, drain and/or gate including at least one first conductive material, and a metal alloy layer disposed on substantially all of a surface of the conductive region, the metal alloy layer including a second conductive material different than the at least one first conductive materials. In one embodiment, the second conductive material includes a cobalt and/or nickel alloy. The metal alloy layer provides a non-epitaxial raised source/drain (and gate) to reduce the parasitic series resistance in, for example, nFETs fabricated on UTSOI. In addition, the metal alloy layer may include a stress to enhance mobility in a channel of the transistor device. The metal alloy layer may be formed using a selective electrochemical metal deposition process such as electroless or electrolytic plating.

A first aspect of the invention provides a transistor device comprising: a conductive region including at least one first conductive material; and a metal alloy layer disposed on substantially all of a surface of the conductive region, the metal alloy layer including a second conductive material different than the at least one first conductive material.

A second aspect of the invention provides a method comprising: forming a conductive region for a transistor device, the conductive region including at least one first conductive material; and forming a metal alloy layer on a surface of the conductive region, the metal alloy layer including a second conductive material different than the at least one first conductive material.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a conventional transistor device.

FIGS. 2-3 show one embodiment of a method of forming a transistor device according to the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

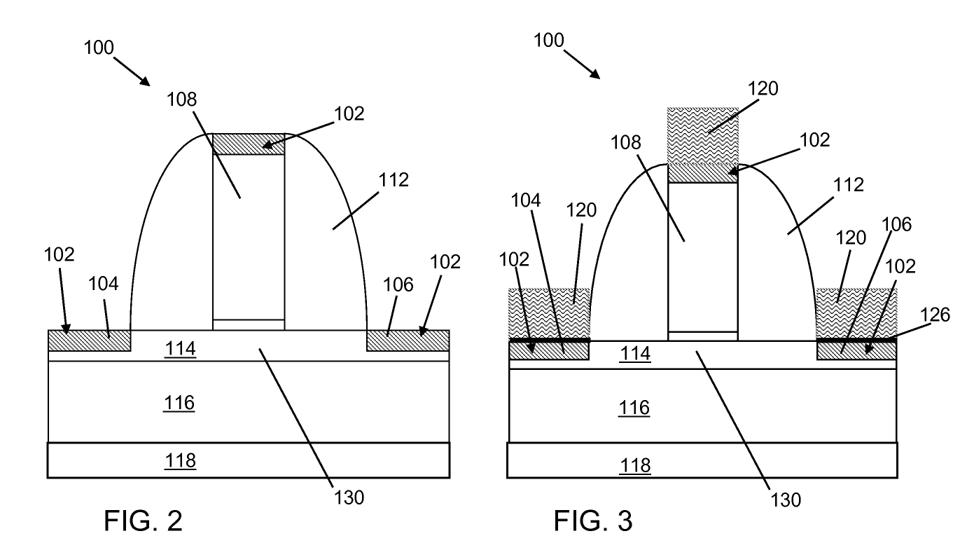

Referring to FIGS. 2-3, one embodiment of a method of forming a transistor device 100 (FIG. 3) according to the invention is illustrated. FIG. 2 shows forming a conductive region(s) 102 for transistor device 100. Conductive region(s) 102 may include, for example, a source 104, a drain 106, a gate 108 and/or any other conductive area of transistor device 100. Conductive region(s) 102 may be formed using any now known or later developed techniques (implantations not shown). At this stage, conductive region(s) 102 include at least one first conductive material such as cobalt silicide and/or nickel silicide. Other conductive materials may also be employed.

As illustrated, transistor device 100 (FIG. 3) may be formed on an ultra-thin silicon-on-insulator (UTSOI) substrate 110 including a silicon 114, a buried silicon oxide (BOX) 116 and a silicon substrate 118. However, the teachings of the invention are not limited to this type substrate. In contrast to the RSD approach, spacer 112 is permanent, and can be reduced in width due to the shallow junction and thin conductive region(s) 102 (silicide).

Next, as shown in FIG. 3, a metal alloy layer 120 is formed on substantially all of a surface of conductive region(s) 102 (as opposed to creation of a contact plugs or vias). Metal alloy layer 120 includes a second conductive material different than the at least one first conductive material. Metal alloy layer 120 does not include re-grown silicon as in the RSD approach. In one embodiment, second conductive material includes at least one of a cobalt alloy and a nickel alloy. More specifically, second conductive material may include CoₙXₘYₚ and/or NiₙXₘYₚ. In this case, X may include tungsten (W), ruthenium (Ru), palladium (Pd), platinum (Pt), rhodium (Rh), rhenium (Re), ytterbium (Yb), yttrium (Y), erbium (Er), iridium (Ir), osmium (Os), iron (Fe), manganese (Mn), vanadium (V), titanium (Ti), chromium (Cr), tantalum (Ta), molybdenum (Mo), zirconium (Zr), hafnium (Hf), scandium (Sc), holmium (Ho), terbium (Tb), gadolinium (Gd), lutetium (Lu), dysprosium (Dy) or zinc (Zn), and Y may include phosphorous (P), boron (B), arsenic (Ar), antimony (Sb), indium (In) or tin (Sn). In any case, n, m and p each have a value ranging from approximately 0 to approximately 99.

As shown in FIG. 3, metal alloy layer 120 may be formed through selective deposition in a self-aligned manner on conductive region(s) 102, which can be confirmed through gate leakage measurement. In one embodiment, metal alloy layer 120 forming includes using an electrochemical technique such as electrolytic plating or electroless plating, i.e., metal alloy layer 120 is non-epitaxially formed. In any event, the deposition is a near room temperature process. The electrochemical process may be preceded by a cleaning to remove oxygen from the surface of conductive region(s) 102. Any electroless plating pre-clean employed does not etch spacer 112 or conductive region(s) 102. In one embodiment, a seed layer 126 (e.g., palladium (Pd)) deposition may occur prior to metal alloy layer 120 formation. However, this is not always necessary.

The above-described embodiments may also be enabled to address the loss of stress in a channel 130 of transistor device 100 caused by the use of thinner silicon 114. As known in the art, tensile stress enhances electron mobility in an nFET type transistor device 100, and a compressive stress enhances hole mobility in a pFET type transistor device 100. In an alternative embodiment, metal alloy layer 120 may include a stress coupled to a channel 130 of transistor device 100. The stress level can be controlled by the manner of deposition, and can be modulated by the composition and thickness of metal alloy layer 120 and the thermal budget of the post-deposition processes. Additionally, the stress level may be controlled by the make up of conductive region(s) 102, e.g., silicide, and middle-of-the-line (MOL) materials deposited underneath and above metal alloy layer 120, respectively, and the thermal cycles used in the fabrication process of the device. Hence, metal alloy layer 120 may be employed to compensate for the loss of an ability to impart stress into channel 130 posed by thinner silicon 114.

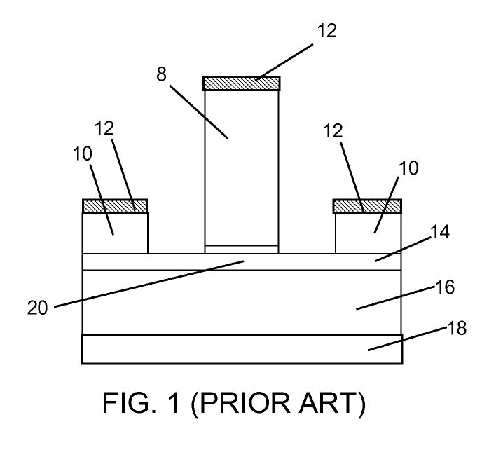

Transistor device 100 includes a conductive region(s) 102 including at least one first conductive material, and metal alloy layer 120 disposed on substantially all of a surface of conductive region(s) 102. As stated above, metal alloy layer 120 includes a second conductive material different than the at least one first conductive material. Metal alloy layer 120 provides a low parasitic resistance contact to source 104, drain 106 and/or gate 108. One reason for the lower parasitic resistance is the thicker conductive material, and another reason is that the silicide and alloy material interface is free of oxygen, thus preventing creation of additional parasitic resistance. As such, metal alloy layer 120 removes the need for an RSD 10 (FIG. 1), thus reducing complexity and costs. The choice of metal alloy layer 120 content and its thickness can be controlled based on the diffusion and resistance value required. This approach is fully compatible with a conventional CMOS process flow for both cobalt and nickel silicides.

### EXAMPLE

In one illustrative implementation, an ultra-thin Si channel nFET was fabricated on lightly doped p-type <100> bonded SOI wafer. The initial SOI layer was thinned by thermal oxidation to target a final channel thickness of 10 nm underneath the gate oxide. Device isolation was achieved using a mesa isolation approach. A traditional polysilicon gate nFET process flow was used to fabricate nMOS transistors with gate lengths down to 20 nm. An ultra-thin layer (60 Å) of nickel or cobalt silicide, commensurate with the thin Si channel, was then formed in the source/drain and gate regions. To decrease the resistance associated with the ultra-thin silicide, a thicker conducting (metal alloy) layer was selectively deposited in the source/drain and gate silicide areas using the above-described embodiments of the invention. A metal alloy layer of cobalt-tungsten-phosphorous (CoWP)(25-50 nm) was selectively deposited on the thin metal silicides with an electroless process. Both cross-sectional scanning electron microscope (XSEMs) and electrical measurement of leakage current showed excellent selectivity for the above-described embodiments.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A transistor device comprising:
a conductive region including at least one first conductive material; and
a metal alloy layer disposed on substantially all of a surface of the conductive region, the metal alloy layer including a second conductive material different than the at least one first conductive material.

2. The transistor device of claim 1, wherein the conductive region includes at least one of a source, drain and gate region of the transistor device.

3. The transistor device of claim 1, wherein the metal alloy layer is self-aligned to the conductive region.

4. The transistor device of claim 1, wherein the metal alloy layer includes at least one of a cobalt alloy and a nickel alloy.

5. The transistor device of claim 1, wherein the second conductive material is selected from the group consisting of: CoₙXₘYₚ or NiₙXₘYₚ, wherein X is selected from the group consisting of: tungsten (W), ruthenium (Ru), palladium (Pd), platinum (Pt), rhodium (Rh), rhenium (Re), ytterbium (Yb), yttrium (Y), erbium (Er), iridium (Ir), osmium (Os), iron (Fe), manganese (Mn), vanadium (V), titanium (Ti), chromium (Cr), tantalum (Ta), molybdenum (Mo), zirconium (Zr), hafnium (Hf), scandium (Sc), holmium (Ho), terbium (Tb), gadolinium (Gd), lutetium (Lu), dysprosium (Dy) and zinc (Zn), and Y is selected from the group consisting of: phosphorous (P), boron (B), arsenic (Ar), antimony (Sb), indium (In) and tin (Sn), and
wherein n, m and p each have a value ranging from approximately 0 to approximately 99.

6. The transistor device of claim 1, wherein the metal alloy layer includes a stress coupled to a channel of the transistor device.

7. The transistor device of claim 1, wherein the first conductive material is selected from the group consisting of: cobalt silicide and nickel silicide.

8. A method comprising:
forming a conductive region for a transistor device, the conductive region including at least one first conductive material; and
forming a metal alloy layer on a surface of the conductive region, the metal alloy layer including a second conductive material different than the at least one first conductive material.

9. The method of claim 8, wherein the conductive region includes at least one of a source, drain and gate region of the transistor device.

10. The method of claim 8, wherein the metal alloy layer provides a low parasitic resistance contact to at least one of the source, drain and gate.

11. The method of claim 8, wherein the metal alloy layer forming includes selectively depositing the second conductive material in a self-aligned manner on the conductive region.

12. The method of claim 8, wherein the metal alloy layer includes at least one of a cobalt alloy and a nickel alloy.

13. The method of claim 8, wherein the second conductive material is selected from the group consisting of: CoₙXₘYₚ or NiₙXₘYₚ, wherein X is selected from the group consisting of: tungsten (W), ruthenium (Ru), palladium (Pd), platinum (Pt), rhodium (Rh), rhenium (Re), ytterbium (Yb), yttrium (Y), erbium (Er), iridium (Ir), osmium (Os), iron (Fe), manganese (Mn), vanadium (V), titanium (Ti), chromium (Cr), tantalum (Ta), molybdenum (Mo), zirconium (Zr), hafnium (Hf), scandium (Sc), holmium (Ho), terbium (Tb), gadolinium (Gd), lutetium (Lu), dysprosium (Dy) and zinc (Zn), and Y is selected from the group consisting of: phosphorous (P), boron (B), arsenic (Ar), antimony (Sb), indium (In) and tin (Sn), and
wherein n, m and p each have a value ranging from approximately 0 to approximately 99.

14. The method of claim 8, wherein the metal alloy layer forming includes using an electrochemical technique.

15. The method of claim 14, wherein the electrochemical technique is one of:
electrolytic plating and electroless plating.

16. The method of claim 8, wherein the metal alloy layer includes a stress coupled to a channel of the transistor device.

17. The method of claim 8, wherein the first conductive material is selected from the group consisting of: cobalt silicide and nickel silicide.

18. The method of claim 8, wherein the metal alloy layer forming is non-epitaxial.

19. The method of claim 8, wherein the metal alloy layer forming includes forming a palladium (Pd) seed layer prior to forming the metal alloy layer.

20. The method of claim 8, further comprising cleaning the conductive region prior to the metal alloy layer forming to remove oxygen from the surface.
